(19) United States
(12) Patent Application Publication
(10) Pub. No.: US 2026/0038581 A1
(43) Pub. Date: Feb. 5, 2026

(54) RECEIVER CIRCUIT FOR DOUBLE DATA RATE MEMORY, AND THE DOUBLE DATA RATE MEMORY USING THE RECEIVER CIRCUIT

(71) Applicant: Shanghai Zhaoxin Semiconductor Co., Ltd., Shanghai (CN)

(72) Inventors: Yi SHI, Beijing (CN); Qiang SI, Beijing (CN)

(21) Appl. No.: 18/964,269

(22) Filed: Nov. 29, 2024

(30) Foreign Application Priority Data
Jul. 31, 2024 (CN) 202411046584.6

(51) Int. Cl. G11C 11/4093; H03F 3/45; H04L 25/03

(52) U.S. Cl. CPC G11C 11/4093; H04L 25/03878; H03F 3/45179; H03F 2203/45022

(57) ABSTRACT

A receiver circuit for double data rate memory is shown, which is operative to receive an input signal. The receiver circuit has two separated input circuits and a load-stage circuit. The first input circuit and the second input circuit in the input stage handle signals of non-overlapping signal swings. The input signal is received by an enabled input circuit of the first and the second input circuits. The load-stage circuit is coupled to the enabled input circuit to form a hybrid cascode circuit of a common-source and common-gate design.

### CROSS REFERENCE TO RELATED APPLICATIONS

This application claims priority of China Patent Application No. 202411046584.6, filed on Jul. 31, 2024, the entirety of which is incorporated by reference herein.

### BACKGROUND OF THE INVENTION

### Field of the Invention

The present invention relates to a double data rate (DDR) memory.

### Description of the Related Art

Double data rate synchronous dynamic random access memory (DDR SDRAM) is generally used as the memory in a personal computer (PC). Low power double data rate synchronous dynamic random access memory (LPDDR SDRAM) is generally used as the memory in consumer electronics (e.g., mobile phones, tablet computers, etc.), and is also known as a mobile DDR SDRAM (mDDR). With the development of 5th generation technology DDR5/LPDDR5, the input/output (I/O) data rate is getting higher and higher; for example, up to 6.4 Gbps, much higher than 3.2 Gpbs, the maximum data rate of the 4th generation technology DDR4. To be compatible with DDR4, DDR5 and LPDDR5 protocols, the I/O terminals of a double data rate (DDR) memory require a special design to flexibly cope with complex and diverse application scenarios.

In particular, the on-die terminal (ODT) of DDR4/DDR5 used in personal computers is connected to the power supply, and the ODT of LPDDR5 used in mobile devices is connected to the ground. The two different DDR types have non-overlapping signal swings and different central level. It is a huge challenge to design a DDR I/O.

### BRIEF SUMMARY OF THE INVENTION

A hybrid cascode circuit is proposed, by which a DDR I/O receiver circuit is made compatible with DDR4, DDR5, and LPDDR5 interface protocols. In addition, the disclosed receiver circuit introduces a negative capacitor (NC) structure to increase the bandwidth of the receiver circuit and effectively increase the data rate of the receiver circuit.

A receiver circuit for double data rate memory is shown, which is operative to receive an input signal. The receiver circuit has two separated input circuits and a load-stage circuit. The first input circuit and the second input circuit in the input stage handle signals of non-overlapping signal swings. The input signal is received by an enabled input circuit of the first and the second input circuits. The load-stage circuit is coupled to the enabled input circuit to form a hybrid cascode circuit of a common-source and common-gate design.

In an exemplary embodiment, the load-stage circuit includes a negative capacitance structure, which significantly improves bandwidth of the receiver circuit.

In an exemplary embodiment, the receiver circuit further comprises a signal processing circuit following the load-stage circuit, operative to perform signal amplification, differential-to-single conversion, and signal buffering.

In an exemplary embodiment, the receiver circuit and logic control circuits of the receiver circuit form a receiving and comparison module. A double data rate memory includes several receiving and comparison modules for reception of the input signal. The different receiving and comparison modules are operated based on the different reference voltages, and thereby generate several single-ended outputs.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a block diagram illustrating a receiver circuit 100 of a double data rate (DDR) memory in accordance with an exemplary embodiment of the disclosure;

FIG. 2 illustrates the details of the LPDDR5 input circuit 102 and a DDR4/DDR5 input circuit 104 in the input stage in accordance with an exemplary embodiment of the disclosure;

FIG. 3 illustrates the details of the load-stage circuit 106 in accordance with an exemplary embodiment of the disclosure;

FIG. 4 illustrates the details of the signal processing circuit 108 in accordance with an exemplary embodiment of the disclosure;

FIG. 5 and FIG. 6 illustrate two logic control circuits 500 and 600, generating control signals for the receiver circuit 100 in accordance with exemplary embodiments of the disclosure; and

FIG. 7 is a block diagram illustrating a double data rate (DDR) memory 700 in accordance with an exemplary embodiment of the disclosure.

### DETAILED DESCRIPTION OF THE INVENTION

The following description enumerates various embodiments of the disclosure, but is not intended to be limited thereto. The actual scope of the disclosure should be defined according to the claims. The various block functions mentioned below may be implemented by a combination of hardware, software, and firmware, and may also be implemented by special circuits. The various blocks and modules are not limited to being implemented separately, but can also be combined together to share certain functions.

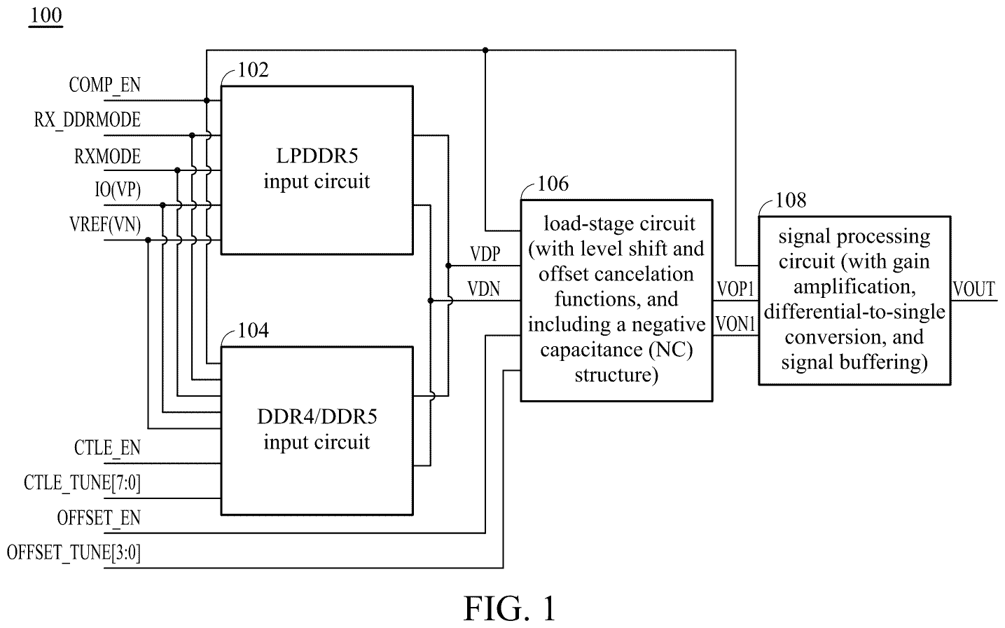

FIG. 1 is a block diagram illustrating a receiver circuit 100 of a double data rate (DDR) memory in accordance with an exemplary embodiment of the disclosure.

The input stage includes an LPDDR5 input circuit 102 and a DDR4/DDR5 input circuit 104, which are selectively enabled by an enable signal RX_DDRMODE depending on the applications. When the LPDDR5 input circuit 102 is enabled, the DDR4/DDR5 input circuit 104 is disabled. Conversely, when the LPDDR5 input circuit 102 is disabled, the DDR4/DDR5 input circuit 104 is enabled. The input signal (IO) received by the DDR and the reference voltage (Vref) form a pair of pseudo differential signals (VP, VN), which is received by the enabled LPDDR5 input circuit 102 or the enabled DDR4/DDR5 input circuit 104, and transferred to the load-stage circuit 106 as a pair of differential signals VDP and VDN. The load-stage circuit 106 includes level shift and offset cancelation functions, and includes a negative capacitance (NC) structure for high-speed operations. A pair of differential outputs VOP1 and VON1 generated by the load-stage circuit 106 are sent to a signal processing circuit 108 for gain amplification, differential-to-single conversion, and signal buffering, and thereby a single-ended output VOUT is generated.

The receiving end of DDR has an on-die termination (ODT) design. The on-die terminal of DDR4 or DDR5 is connected to the power supply. The on-die terminal of LPDDR5 is grounded. The two different DDR types have non-overlapping signal swings, and the different central levels.

In order to be compatible with LPDDR5, DDR4, and DDR5, the enabled input circuit of the LPDDR5 input circuit 102 and the DDR4/DDR5 input circuit 104 in the input stage is combined with the load-stage circuit 106 to form a hybrid cascode circuit. In such a structure, the whole input stage (including 102 and 104) operates in the VPP power domain (related to the active voltage VPP of the DDR device). Thus, the non-overlapping signal swings of the DDR4 (or DDR5) receiver and the LPDDR5 receiver are properly handled, so as the different central levels of the DDR4 (or DDR5) receiver and the LPDDR5 receiver.

In addition to receiving the enable signal RX_DDRMODE, the input signal IO(VP), and the reference voltage VREF(VN), the common inputs for the LPDDR5 input circuit 102 and the DDR4/DDR5 input circuit 104 include a receiver enable signal COMP_EN (to turn on the whole receiver circuit 100) and a current selection signal (for setting the gain amplification of the input stage) RXMODE.

Since the DDR4/DDR5 input circuit 104 is equipped with a continuous time linear equalizer (CTLE), the DDR4/DDR5 input circuit 104 further receives a CTLE enable signal CTLE_EN and the CTLE adjustment signal CTLE_TUNE[7:0]. The continuous time linear equalizer (CTLE) provided by the DDR4/DDR5 input circuit 104 is adaptable.

This paragraph describes the level shift and offset cancellation functions provided by the load-stage circuit 106, and introduces the negative capacitance (NC) structure formed in the load-stage circuit 106. The level shift circuit shifts the operating level from the VPP power domain to a DVDD power domain (related to the digital voltage DVDD, which is lower than VPP). The offset cancellation design deletes the offset introduced by the receiver circuit 100. The negative capacitance (NC) structure and the offset cancellation circuit specifically form a positive feedback circuit, which effectively increases the bandwidth of the receiver circuit 100. The input signals of the load-stage circuit 106 include the enable signal COMP_EN, the offset cancellation enable signal OFFSET_EN, and the offset adjustment signal OFFSET_TUNE[3:0]. The load-stage circuit 106 outputs the pair differential outputs VOP1 and VON1.

This paragraph describes the gain amplification and differential-to-single conversion provided by the signal processing circuit 108. The gain amplification circuit increases the gain of the whole receiver circuit 100. The differential-to-single conversion circuit is implemented with a single-ended rail-to-rail component (such as a CMOS), to facilitate subsequent circuit processing. The signal processing circuit 108 operates in the DVDD power domain.

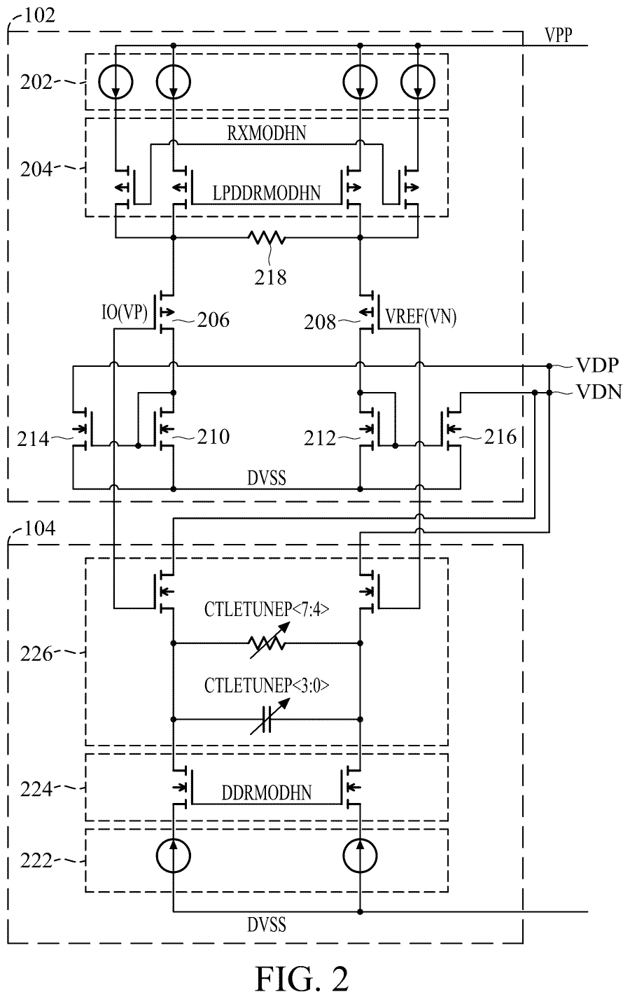

FIG. 2 illustrates the details of the LPDDR5 input circuit 102 and a DDR4/DDR5 input circuit 104 in the input stage in accordance with an exemplary embodiment of the disclosure.

The LPDDR5 input circuit 102 includes four PMOS current sources 202, four enable control PMOSs 204, two input PMOSs (206 and 208, forming a common-source PMOS pair), two load NMOSs (210 and 212, or named a load NMOS pair), two NMOSs (214 and 216, forming a common-source NMOS pair) connected to the next stage, and a resistor 218 for negative feedback on sources of the two input PMOSs (206 and 208). The signals IO(VP) and VREF(VN) are received by the gates of the common-source PMOS pair (206 and 208). The drains of the common-source PMOS pair (206 and 208) are coupled to the drains of the load NMOS pair (210 and 212). The sources of the load NMOS pair (210 and 212) are coupled to the sources of the common-source NMOS pair (214 and 216). As shown, a pair of differential signals VDP and VDN is presented at the drains of the common-source NMOS pair (214 and 216), and is coupled to load-stage circuit 106. The LPDDR5 input circuit 102 is in a PMOS (206/208)-NMOS (210/212)-NMOS (214/216) architecture, and includes a feedback design on sources of the input PMOSs (206/208). The bandwidth of the LPDDR5 input circuit 102 is effectively improved.

The DDR4/DDR5 input circuit 104 includes two NMOS current sources (222), two enable control NMOSs (224), and a continuous time linear equalizer (CTLE) 226. The continuous time linear equalizer (CTLE) 226 receives the signals IO(VP) and VREF(VN) by a common-source NMOS pair. After the continuous time linear equalization, the drains of the common-source NMOS pair output the differential signals VDP and VDN. The continuous time linear equalizer (CTLE) 226 uses an adjustable resistor and an adjustable capacitor to implement an adjustable CTLE. The adjustable CTLE effectively increases the bandwidth of the DDR4/DDR5 input circuit 104 and considerably reduces the InterSymbol Interference (ISI). The illustrated signal CTLETUNEP<7:0> is derived from the CTLE adjustment signal CTLE_TUNE[7:0]. The signal CTLETUNEP<7:4> controls the adjustable resistor, and the signal CTLETUNEP<3:0> controls the adjustable capacitor.

The following is an example of DDR mode setting.

In LPDDR5 mode, COMP_EN=1′b1, and RX_DDRMODE=1′b0. The NMOS current sources (222) of the DDR4/DDR5 input circuit 104 are turned off by the enable control NMOSs (224). The PMOS current sources (202) of the LPDDR5 input circuit 102 are turned on by the enable control PMOS (204). The input reference voltage Vref ranges from about 0.05*VPP to 0.5*VPP, which is suitable for the low-power design of LPDDR5. The following shows the design for the current selection signal RXMODE that adjusts the gain of the input stage circuit. When RXMODE=1′b1, the circuit gain is small and the bandwidth is relatively high, which is suitable for high-speed situations. When RXMODE=1′b0, the circuit gain is large and the bandwidth is relatively small, which is suitable for low-speed situations. Which setting to use needs to be verified at the silicon level (silicon validation). By default, RXMODE is set to 1′b1. The current selection signal RXMODE is transformed to the signal RXMODHN to operate the illustrated components.

In DDR5 mode, COMP_EN=1′b1 and RX_DDRMODE=1′b1. The NMOS current sources (222) of the DDR4/DDR5 input circuit 104 are turned on by the enable control NMOSs (224). The PMOS current sources (202) of the LPDDR5 input circuit 102 are turned off by the enable control PMOSs (204_. The input reference voltage Vref ranges from approximately 0.5*VPP˜0.95*VPP, which is suitable for the operations of DDR5. The following shows the design for the current selection signal RXMODE that adjusts the gain of the input stage circuit. When RXMODE=1′b0, the circuit gain is small and the bandwidth is relatively high, which is suitable for high-speed situations. When RXMODE=1′b1, the circuit gain is large and the bandwidth is relatively small, which is suitable for low speed situations. Which setting to use needs to be verified at the silicon level (silicon validation). By default, RXMODE is set to 1′b0.

The differential output terminals of the LPDDR5 input circuit 102 and the differential output terminals of the DDR4/DDR5 input circuit 104 are connected together to generate the pair of differential signals VDP and VDN for the load-stage circuit 106. The enabled input circuit (102 or 104) and the load-stage circuit 106 form a hybrid cascode circuit. The differential signals VDP and VDN are the common-source differential signals output from the input stage, and are used as common-gate differential signals input the load-stage circuit 106.

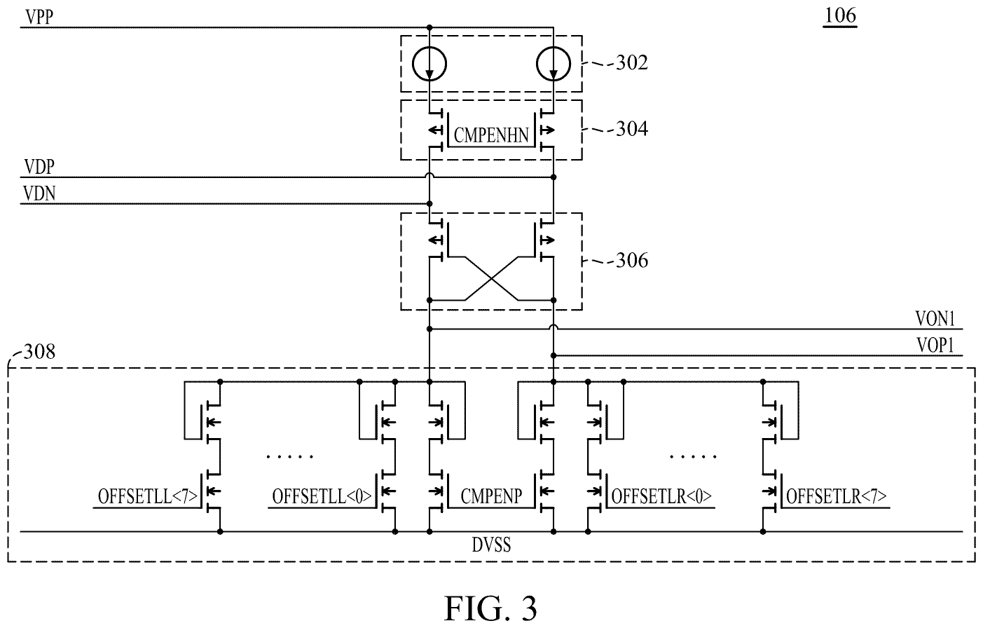

FIG. 3 illustrates the details of the load-stage circuit 106 in accordance with an exemplary embodiment of the disclosure.

The load-stage circuit 106 includes two PMOS current sources (302), two common-gate enable control PMOSs (304, or named a common-gate PMOS pair), two PMOSs (306, or named a cross-coupled PMOS pair) in the negative capacitance (NC) structure, and an offset cancellation circuit 308. The differential signals VDP and VDN are coupled to the drains of the common-gate PMOS pair 304 as well as the sources of the cross-coupled PMOS pair 306 of the negative capacitance (NC) structure. By passing through the cross-coupled PMOS pair 306 of the negative capacitance (NC) structure, the differential signals VDP and VDN are further coupled to the offset cancellation circuit 308. The offset cancellation circuit 308 includes diode-connected NMOSs, which are connected in parallel. Each diode-connected NMOS is connected in series with one enable NMOS. The load-stage circuit 106 also operates in the VPP power domain.

The negative capacitance (NC) structure comprising the cross coupled PMOS pair 306 realizes the function of a conventional level shifter. Thus, a conventional level shifter for high-to-low conversion is not required. The offset cancellation circuit 308 cancels the offset introduced by the receiver circuit 100 itself. The negative capacitance structure (306) and the offset cancellation circuit 308 form a positive feedback circuit, which effectively improves the bandwidth of the receiver circuit 100.

As shown, the load-stage circuit 106 is enabled based on the signals CMPENHN and CMPENP, which are derived from the enable signal COMP_EN. The offset cancellation circuit 308 is controlled by the signals OFFSETLL<7:0> and OFFSETLR<7:0>, which are derived from the offset cancellation enable signal OFFSET_EN and the offset adjustment signal OFFSET_TUNE[3:0].

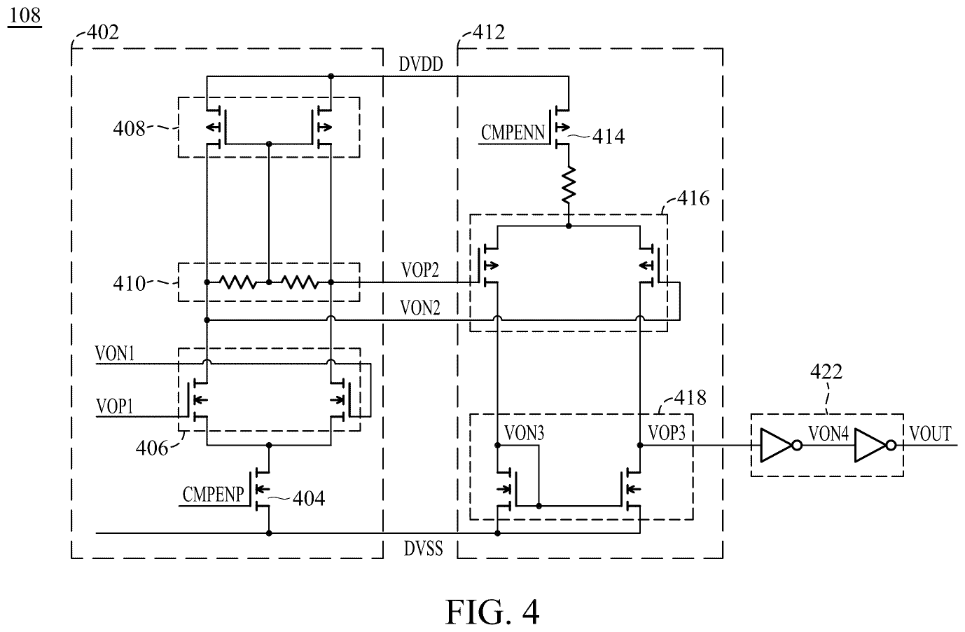

FIG. 4 illustrates the details of the signal processing circuit 108 in accordance with an exemplary embodiment of the disclosure. The signal processing circuit 108 operates in the DVDD power domain.

Considering the sufficient bandwidth for processing the input signal, the gain of the input circuit 102/104 is generally set at about 0 dB. In order to amplify the received signal, the signal processing circuit 108 uses a classic medium-gain common-source amplifier to implement the gain amplification circuit 402, which includes an enable control NMOS 404 (controlled by the signal CMPENP), two input NMOSs (406), two load PMOSs (408) and two resistors (410).

In order to facilitate the subsequent logic processing, the differential signals need to be converted into a single-ended rail-to-rail signal (complying with the CMOS operating voltages) and is output by passing through a buffer circuit. As shown, the signal processing circuit 108 includes a differential-to-single conversion structure 412 implemented by a common-source amplifier, which includes an enable control PMOS 414 (controlled by signal CMPENN, which is derived from the enable signal COMP_EN), a input PMOS pair 416, and two load NMOSs (418). The buffer circuit 422 includes two inverters connected in series.

The differential outputs VOP1 and VON1 output from the load-stage circuit 106 are received by the signal processing unit 108, and amplified by the gain amplification circuit 402 to generate the differential outputs VOP2 and VON2. The differential-to-single conversion structure 412 converts the differential outputs VOP2 and VON2 to differential outputs VOP3 and VON3, and takes the positive differential output VOP3 as a signal-end output. The signal output VOP3 then is inverted into a signal VON4, and then further inverted into the single-ended output VOUT.

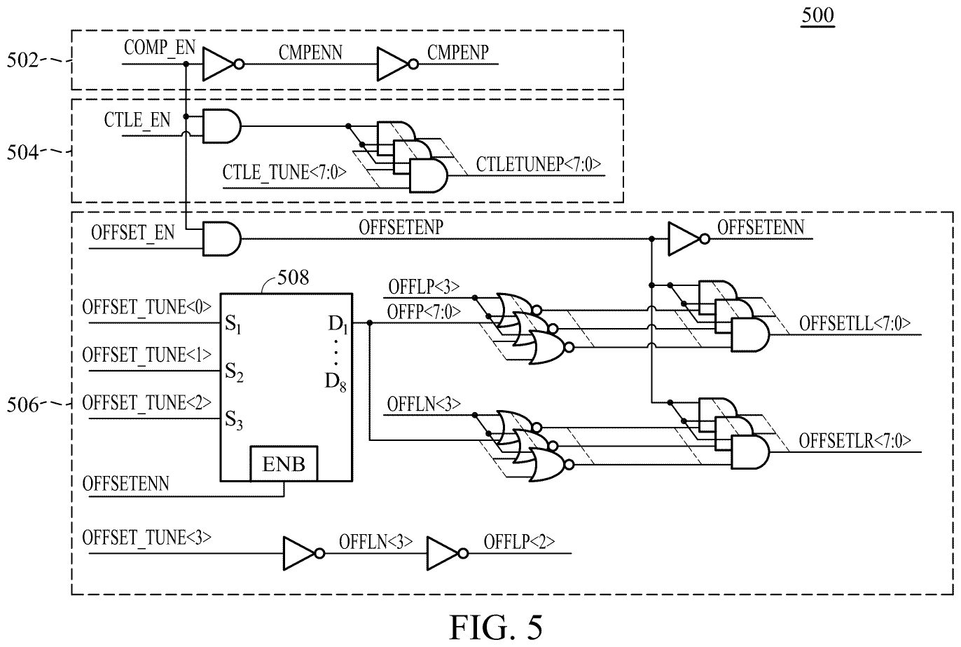

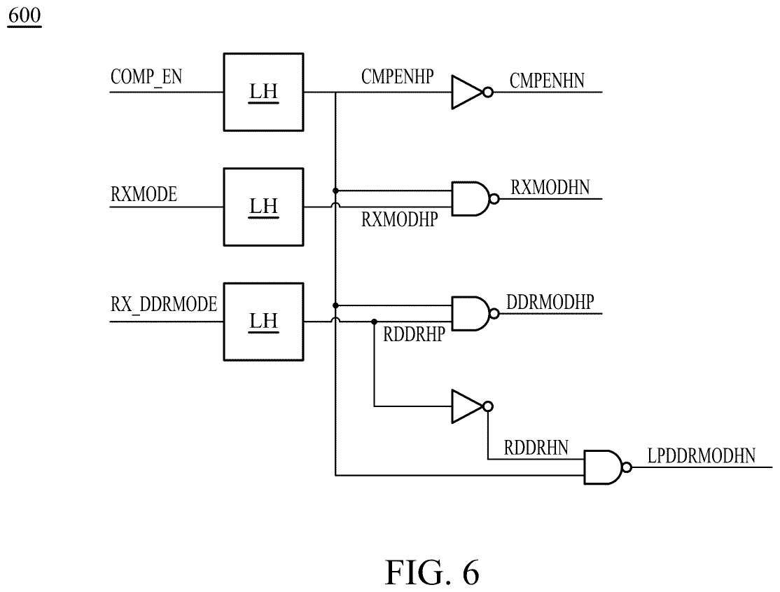

FIG. 5 and FIG. 6 illustrate two logic control circuits 500 and 600, generating control signals for the receiver circuit 100 in accordance with exemplary embodiments of the disclosure.

Referring to FIG. 5, the logic control circuit 500 operates in the DVDD power domain and includes an enable control circuit 502 (generating control signals which are derived from the enable signal COMP_EN), a continuous time linear equalizer (CTLE) control circuit 504 (generating control signals which are derived from the CTLE enable signal CTLE_EN, and the CTLE adjustment signal CTLE_TUNE[7:0]), and the offset cancellation control circuit 506 (generating control signals which are derived from the offset cancellation enable signal OFFSET_EN, and the offset adjustment signal OFFSET_TUNE[3:0]).

The offset cancellation control circuit 506 includes one 3-to-8 decoder 508. By default, the offset cancellation function is disabled, and the control signals generated by the offset cancellation control circuit 506 turn on all current sources of the offset cancellation circuit. When the offset cancellation function is enabled, the offset cancellation control circuit 506 controls on/off status of the left branch current sources and the right branch current sources within the offset cancellation circuit, and thereby offset cancellation is achieved.

Referring to FIG. 6, a logic control circuit 600 operating in the VPP power domain is shown, which includes a level shift components LH for the control signals, operative to increase the voltage level from the DVDD power domain to the VPP power domain. The logic control circuit 600 further includes logic gates operative to further process the enable signal COMP_EN, the enable signal RX_DDRMODE, and the current selection signal RXMODE.

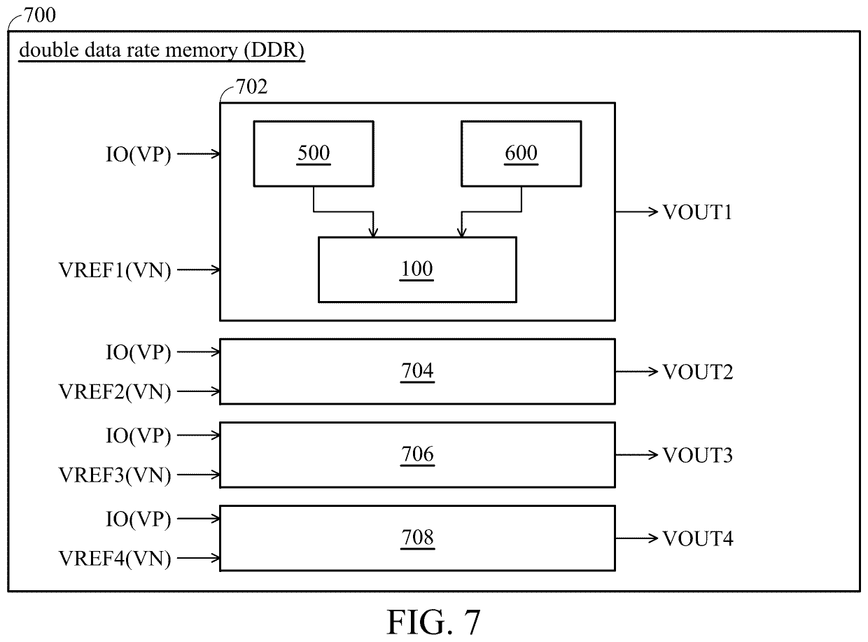

FIG. 7 is a block diagram illustrating a double data rate (DDR) memory 700 in accordance with an exemplary embodiment of the disclosure, which includes a plurality of receiving and comparison modules 702, 704, 706, and 708. Each receiving and comparison module (702/704/706/708) includes the aforementioned logic control circuits 500 and 600 and the receiver circuit 100. The receiving and comparison modules 702, 704, 706, and 708 respectively receive the different reference voltages Vref1, Vref2, Vref3, and Vref4 as the differential negative input VN. Based on the four different reference voltages Vref1, Vref2, Vref3, and Vref4, the input signal IO transferred to the receiving and comparison modules 702, 704, 706, and 708 (as the differential positive input VP) are converted to four different single-ended outputs VOUT1, VOUT2, VOUT3, and VOUT4.

Any combo DDR device having a receiver circuit that provides the proposed hybrid cascode circuit (formed by an enabled input circuit and a load-stage circuit) falls within the scope of disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A receiver circuit, used in a double data rate memory to receive an input signal, comprising:
a first input circuit and a second input circuit in an input stage, provided to handle signals of non-overlapping signal swings, wherein the input signal is received by an enabled input circuit of the first input circuit and the second input circuit; and
a load-stage circuit, coupled to the enabled input circuit to form a hybrid cascode circuit with a common-source and common-gate design.

2. The receiver circuit as claimed in claim 1, wherein:
the enabled input circuit outputs a pair of differential signals to the load-stage circuit;
the load-stage circuit includes a negative capacitance structure, by which voltage levels of the pair of differential signals are shifted to generate a first pair of differential outputs.

3. The receiver circuit as claimed in claim 2, wherein:
the load-stage circuit further includes an offset cancellation circuit, which is combined with the negative capacitor structure to form a positive feedback circuit that increases a bandwidth of the receiver circuit.

4. The receiver circuit as claimed in claim 3, wherein:
the first input circuit includes a common-source PMOS pair, a load NMOS pair coupled to the common-source PMOS pair, and a first common-source NMOS pair coupled to the common-source PMOS pair,
wherein:
PMOS is an abbreviation of p-channel metal oxide semiconductor field transistor and NMOS is an abbreviation of n-channel metal oxide semiconductor field transistor;
the first input circuit uses the common-source PMOS pair to receive the input signal as well as a reference voltage; and
the pair of differential signals are presented at drains of the first common-source NMOS pair.

5. The receiver circuit as claimed in claim 4, wherein:
the first input circuit further includes a plurality of PMOS current sources and a plurality of enable control PMOSs corresponding to the plurality of PMOS current sources, operative to generate currents to drive the common-source PMOS pair; and
the first input circuit further has a resistor coupled between sources of the common-source PMOS pair to provide negative feedback to the sources of the common-source PMOS pair.

6. The receiver circuit as claimed in claim 5, wherein:
the load-stage circuit receives the pair of differential signals at drains of a common-gate PMOS pair.

7. The receiver circuit as claimed in claim 6, wherein:
the negative capacitance structure includes a cross-coupled PMOS pair, whose sources are coupled to the drains of the common-gate PMOS pair.

8. The receiver circuit as claimed in claim 7, wherein:
drains of the cross-coupled PMOS pair are coupled to the offset cancellation circuit; and
the offset cancellation circuit includes a plurality of diode-connected NMOSs which are connected in parallel, wherein each diode-connected NMOS is connected in series with an enable NMOS.

9. The receiver circuit as claimed in claim 8, wherein:
the second input circuit includes a continuous time linear equalizer, which uses a second common-source NMOS pair to receive the input signal as well as the reference voltage for continuous time linear equalization, and generate the pair of differential signals at drains of the second common-source NMOS pair.

10. The receiver circuit as claimed in claim 9, wherein:
the continuous time linear equalizer includes an adjustable capacitor and an adjustable resistor connected in parallel between sources of the second common-source NMOS pair.

11. The receiver circuit as claimed in claim 10, wherein:
the second input circuit further includes a plurality of NMOS current sources and a plurality of enable control NMOSs corresponding to the NMOS current sources, operative to generate currents to drive the second common-source NMOS pair.

12. The receiver circuit as claimed in claim 11, wherein:
when the first input circuit is enabled, the second input circuit is disabled; and
when the first input circuit is disabled, the second input circuit is enabled.

13. The receiver circuit as claimed in claim 12, wherein:
the first input circuit is enabled to implement a low-power double data rate memory; and
the second input circuit is enabled to implement a double data rate memory that consumes more power than the low-power double data rate memory.

14. The receiver circuit as claimed in claim 3, further comprising:
a signal processing circuit, receiving the first pair of differential outputs, and performing a differential-to-single conversion to generate a single-ended output.

15. The receiver circuit as claimed in claim 14, wherein:
the signal processing circuit further includes a gain amplifier, which amplifies the first pair of differential outputs to generate a second pair of differential outputs, and then performs the differential-to-single conversion on the second pair of differential outputs.

16. The receiver circuit as claimed in claim 15, wherein:
the signal processing circuit uses a differential-to-single conversion structure to convert the second pair of differential outputs into a third pair of differential outputs; and
the signal processing circuit further includes a buffer circuit, which receives a positive differential output of the third pair of differential outputs, and generates the single-ended output after an even number of signal inversions.

17. The receiver circuit as claimed in claim 16, wherein:
the differential-to-single conversion structure is a common source amplifier.

18. The receiver circuit as claimed in claim 14, wherein:
the input stage operates in a first power domain;
through the load-stage circuit, the first power domain is down shifted to a second power domain; and
the signal processing circuit operates in the second power domain.

19. A double data rate memory, comprising:
the receiver circuit as claimed in claim 18;
a first logic control circuit operating in the second power domain, generating control signals to the input stage and the load-stage circuit, to control components operating in the second power domain; and
a second logic control circuit operating in the first power domain, generating control signals to the signal processing circuit and the load-stage circuit, to control components operating in the first power domain.

20. The double data rate memory as claimed in claim 19, wherein:
the receiver circuit, the first logic control circuit, and the second logic control circuit form a receiving and comparison module; and
the double data rate memory includes a plurality of receiving and comparison modules, wherein in addition to receiving the input signal, the different receiving and comparison modules receive reference voltages of different levels, to generate a plurality of single-ended outputs.
